(19) United States
(12) Patent Application Publication
(10) Pub. No.: US 2020/0220368 A1
(43) Pub. Date: Jul. 9, 2020

(54) Universal Adapter

(71) Applicant: Google LLC, Mountain View, CA (US)

(72) Inventors: Chao Fei, San Jose, CA (US); Honggang Sheng, Milpitas, CA (US); Douglas Osterhout, San Jose, CA (US); Srikanth Lakshmikanthan, Milpitas, CA (US)

(21) Appl. No.: 16/242,517

(22) Filed: Jan. 8, 2019

(51) Int. Cl. H02J 7/00; H02M 3/158; H02M 1/14; G01R 19/165; H02M 3/335; H02M 7/10

(52) U.S. Cl. CPC H02J 7/0055; H02M 3/1584; H02M 1/14; H02M 2001/0006; H02M 3/3353; H02M 7/103; H02J 7/0081; G01R 19/16542

(57) ABSTRACT

An adapter can include a voltage doubler rectifier, a first stage converter, and a second stage converter. The voltage doubler rectifier can have a switch and can be configured to rectify a received voltage in response to the switch being in a first position, and to rectify and effectively double the received voltage in response to the switch being in a second position. The first stage converter can be coupled to the voltage doubler rectifier and can be a first type of converter. The first type of converter can be either an isolated converter or a non-isolated converter. The second stage converter can be coupled to the first stage converter and can be a second type of converter. The second type of converter can be either the isolated converter or the non-isolated converter. The second type of converter can be different from the first type of converter.

### BACKGROUND

Improvements in semiconductor manufacturing techniques have enabled greater numbers of transistors to be realized in a given amount of area on an integrated circuit. These improvements have not only increased the processing power of electronic devices that incorporate such integrated circuits, but also have enabled the size of such electronic devices to be reduced. This reduction in size has facilitated the development of categories of electronic devices referred to as portable electronic devices and mobile electronic devices. Portable and mobile electronic devices can include, for example, laptops, notebooks, tablets, personal digital assistants, cell phones, smart phones, and the like. Portable and mobile electronic devices can be expected to be operated for significant durations of time while receiving electrical power from batteries. For this reason, these electronic devices can include internal converters designed to produce electrical power at appropriate voltages for various internal circuits in response to receiving electrical power from the batteries at voltages produced by the batteries. Additionally, adapters have been developed to produce electrical power at the voltages produced by the batteries in response to receiving electrical power from wall sockets at voltages supplied to the wall sockets. Having such circuits housed in adapters rather than in corresponding electronic devices has furthered efforts to reduce the size of such electronic devices.

### BRIEF SUMMARY

According to an implementation of the disclosed technologies, an adapter can include a voltage doubler rectifier, a first stage converter, and a second stage converter. The voltage doubler rectifier can have a switch and can be configured to rectify a received voltage in response to the switch being in a first position, and to rectify and effectively double the received voltage in response to the switch being in a second position. The first stage converter can be coupled to the voltage doubler rectifier and can be a first type of converter. The first type of converter can be either an isolated converter or a non-isolated converter. The second stage converter can be coupled to the first stage converter and can be a second type of converter. The second type of converter can be either the isolated converter or the non-isolated converter. The second type of converter can be different from the first type of converter.

According to an implementation of the disclosed technologies, a circuit can include a first diode, a second diode, a third diode, a fourth diode, a first capacitor, a second capacitor, a third capacitor, a first inductor, a second inductor, a third inductor, a primary winding of a transformer, a first secondary winding of the transformer, a second secondary winding of the transformer, a first switch, a second switch, a third switch, a fourth switch, a fifth switch, a sixth switch, a seventh switch, an eighth switch, and a ninth switch. The first diode can have a cathode connected to a first node, and an anode connected to a second node. The second diode can have a cathode connected to the first node, and an anode connected to a third node. The third diode can have a cathode connected to the second node, and an anode connected to a fourth node. The fourth diode can have a cathode connected to the third node, and an anode connected to the fourth node. The first capacitor can be coupled between the first node and a fifth node. The second capacitor can be coupled between the fourth node and the fifth node. The first switch can be coupled between the third node and the fifth node. The second switch can be coupled between the first node and a sixth node. The third switch can be coupled between the fourth node and the sixth node. The third capacitor can be coupled between the sixth node and a seventh node. The first inductor can be coupled between the seventh node and an eighth node. The second inductor can be coupled between the eighth node and the fourth node. The primary winding can be coupled between the eighth node and the fourth node. The first secondary winding can be coupled between a ninth node and a tenth node. The second secondary winding can be coupled between the tenth node and an eleventh node. The fourth switch can be coupled between the ninth node and a twelfth node. The fifth switch can be coupled between the eleventh node and the twelfth node. The sixth switch can be coupled between the tenth node and a thirteenth node. The seventh switch can be coupled between the twelfth node and the thirteenth node. The third inductor can be coupled between the thirteenth node and a fourteenth node. The eighth switch can be coupled between the fourteenth node and a fifteenth node. The ninth switch can be coupled between the twelfth node and the fourteenth node.

According to an implementation the disclosed technologies, a method for producing, from a voltage of an electrical power supply, a voltage that matches a voltage rating of a battery of an electronic device can include determining, by a circuit, the voltage rating of the battery of the electronic device. The electronic device can be separate from the circuit, but can be connected to the circuit. The method can include determining, by the circuit, the voltage of the electrical power supply. The electrical power supply can be separate from the circuit, but can be connected to the circuit. The method can include causing, by the circuit and in response to a determination that the voltage of the electrical power supply is greater than a threshold voltage, a switch to be in a first position. The method can include causing, by the circuit and in response to a determination that the voltage of the electrical power supply is less than the threshold voltage, the switch to be in a second position. The method can include rectifying, by the circuit, a voltage received by the electrical power supply to produce a rectified voltage. The method can include effectively doubling, by the circuit and in response to the switch being in the second position, the rectified voltage. The method can include converting, by a first stage of the circuit, the rectified voltage to produce an intermediate voltage. The method can include converting, by a second stage of the circuit, the intermediate voltage to produce the voltage that matches the voltage rating of the battery of the electronic device. The first stage can be a first type. The first type can be one of a type that includes galvanic isolation or a type that lacks galvanic isolation. The second stage can be a second type. The second type can be one of the type that includes galvanic isolation or the type that lacks galvanic isolation. The second type can be different from the first type.

According to an implementation the disclosed technologies, a system for producing, from a voltage of an electrical power supply, a voltage that matches a voltage rating of a battery of an electronic device can include means for determining the voltage rating of the battery of the electronic device. The system can include means for determining the voltage of the electrical power supply. The system can include means for causing, in response to a determination that the voltage of the electrical power supply is greater than a threshold voltage, a switch to be in a first position. The system can include causing, in response to a determination that the voltage of the electrical power supply is less than the threshold voltage, the switch to be in a second position. The system can include means for rectifying a voltage received by the electrical power supply to produce a rectified voltage. The system can include means for effectively doubling, in response to the switch being in the second position, the rectified voltage. The system can include means for converting the rectified voltage to produce an intermediate voltage. The system can include means for converting the intermediate voltage to produce the voltage that matches the voltage rating of the battery of the electronic device. The means for converting the rectified voltage can be a first type. The first type can be one of a type that includes galvanic isolation or a type that lacks galvanic isolation. The means for converting the intermediate voltage can be a second type. The second type can be one of the type that includes galvanic isolation or the type that lacks galvanic isolation. The second type can be different from the first type.

Additional features, advantages, and embodiments of the disclosed technologies are set forth or apparent from consideration of the following detailed description, drawings, and claims. Moreover, it is to be understood that both the foregoing summary and the following detailed description are illustrative and are intended to provide further explanation without limiting the scope of the claims.

### BRIEF DESCRIPTION OF THE DRAWINGS

The accompanying drawings, which are included to provide a further understanding of the disclosed technologies, are incorporated in and constitute a part of this specification. The drawings also illustrate embodiments of the disclosed technologies and together with the detailed description serve to explain the principles of implementations of the disclosed technologies. No attempt is made to show structural details in more detail than may be necessary for a fundamental understanding of the disclosed technologies and various ways in which it may be practiced.

FIG. 1 is a block diagram of an example of an adapter, according to the disclosed technologies.

FIG. 2 is a block diagram of an example implementation of the adapter illustrated in FIG. 1 in which a switch of a voltage doubler rectifier includes a pair of parallel connections of a transistor and a diode.

FIG. 3 is a block diagram of an example implementation of the adapter illustrated in FIG. 1 in which the adapter includes a filter.

FIG. 4 is a block diagram of another example implementation of the adapter illustrated in FIG. 1 in which the adapter includes a filter.

FIG. 5 is a block diagram of an example of the filter illustrated in FIGS. 3 and 4.

FIG. 6 is a block diagram of an example implementation of the adapter illustrated in FIG. 1 in which the adapter includes a comparator.

FIG. 7 is a block diagram of an example implementation of the adapter illustrated in FIG. 1 in which the adapter includes a bulk capacitor.

FIG. 8 is a block diagram of an example implementation of the adapter illustrated in FIG. 1 in which the adapter includes a regulator for a first stage converter.

FIG. 9 is a block diagram of an example of the first stage converter illustrated in FIG. 1.

FIG. 10 is a block diagram of an example of the first stage converter illustrated in FIG. 9 in which each of the switches includes a parallel connection of a transistor and a diode.

FIG. 11 is a block diagram of an example implementation of the adapter illustrated in FIG. 1 in which the adapter includes a regulator for a second stage converter.

FIG. 12 is a block diagram of an example of the second stage converter illustrated in FIG. 1.

FIG. 13 is a block diagram of an example of the second stage converter illustrated in FIG. 12 in which each of the switches includes a parallel connection of a transistor and a diode.

FIG. 14 is a block diagram of an example implementation of the adapter illustrated in FIG. 1 in which the adapter includes voltage determination circuitry.

FIG. 15 is a flow diagram of an example of a method for producing, from a voltage of an electrical power supply, a voltage that matches a voltage rating of a battery of an electronic device, according to the disclosed technologies.

FIG. 16 is a diagram of an example environment for a security system integrated in a smart home environment.

FIG. 17 is a block diagram of an example of a premises management device.

FIG. 18 is a block diagram of an example of a premises management system.

FIG. 19 is a block diagram of an example of a computing device suitable for implementing certain devices.

### DETAILED DESCRIPTION

As used herein, a statement that a component can be “configured to” perform an operation can be understood to mean that the component requires no structural alterations, but merely needs to be placed into an operational state (e.g., be provided with electrical power, have an underlying operating system running, etc.) in order to perform the operation.

Improvements in semiconductor manufacturing techniques have enabled greater numbers of transistors to be realized in a given amount of area on an integrated circuit. These improvements have not only increased the processing power of electronic devices that incorporate such integrated circuits, but also have enabled the size of such electronic devices to be reduced. This reduction in size has facilitated the development of categories of electronic devices referred to as portable electronic devices and mobile electronic devices. Portable and mobile electronic devices can include, for example, laptops, notebooks, tablets, personal digital assistants, cell phones, smart phones, and the like. Portable and mobile electronic devices can be expected to be operated for significant durations of time while receiving electrical power from batteries. For this reason, these electronic devices can include internal converters designed to produce electrical power at appropriate voltages for various internal circuits in response to receiving electrical power from the batteries at voltages produced by the batteries. Additionally, adapters have been developed to produce electrical power at the voltages produced by the batteries in response to receiving electrical power from wall sockets at voltages supplied to the wall sockets. Having such circuits housed in adapters rather than in corresponding electronic devices has furthered efforts to reduce the size of such electronic devices.

It is not uncommon for an individual to possess more than one portable or mobile electronic device. Often, the voltage produced by the battery of a first portable or mobile electronic device (e.g., a laptop) is different from the voltage produced by the battery of a second portable or mobile electronic device (e.g., a smartphone). This has necessitated having one adapter configured to be used with the first portable or mobile electronic device (e.g., the laptop) and another adapter configured to be used with the second portable or mobile electronic device (e.g., the smartphone). This situation can detract from the quality of the experience of the individual who possesses more than one portable or mobile electronic device because such an individual not only must keep track of which adapter is associated with which portable or mobile electronic device, but also may need to carry such adapters along with the portable or mobile electronic devices. Additionally, the voltage of electrical power supplied to a wall socket varies from one region to another. For example, electrical power is supplied to wall sockets in the Americas at 120 volts, in Japan at 100 volts, and for most of the rest of the world at 220 or 230 volts. This fact can further detract from the quality of the experience of the individual who possesses more than one portable or mobile electronic device because such an individual may also need to carry one or more converters to produce electrical power at the voltage used by an adapter in response to receiving electrical power from various wall sockets at the voltages supplied to these various wall sockets.

The disclosed technologies include an adapter configured to determine a voltage rating of a battery of a load connected to the adapter, to determine a voltage of an electrical power supply at a wall socket to which the adapter is connected, and to produce, from the voltage of the electrical power supply, a voltage that matches the voltage rating of the battery.

Advantageously, in comparison with a conventional adapter that is rated for a specific operating temperature, an adapter configured according to the disclosed technologies can be realized with components having smaller sizes and less power loss, which, in turn, can allow for the adapter to have a higher power density and a higher power level in a smaller volume.

Advantageously, an adapter configured according to the disclosed technologies can be configured to operate close to a resonant frequency of at least some of the reactance components of the adapter, which can reduce the reactance portion of the impedance of the adapter.

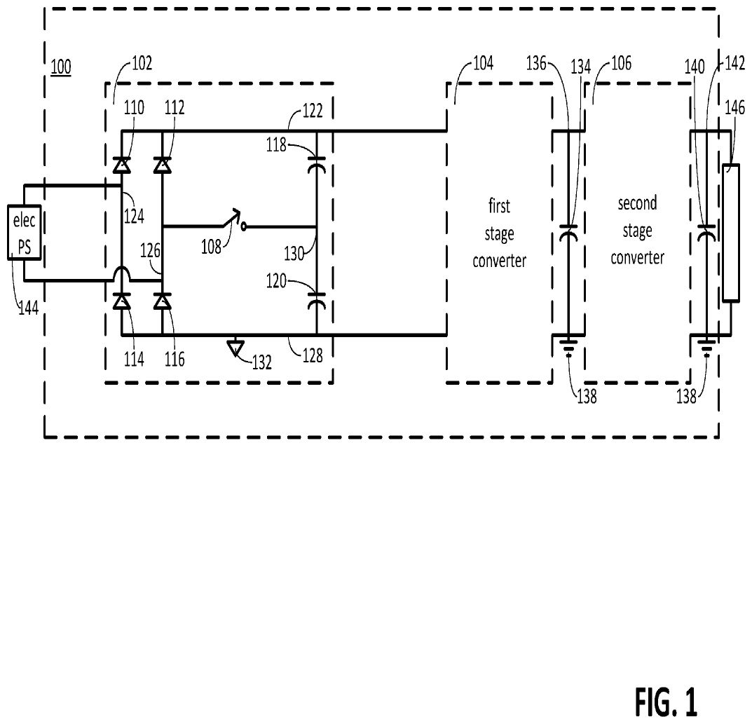

FIG. 1 is a block diagram of an example of an adapter 100, according to the disclosed technologies. The adapter 100 can include, for example, a voltage doubler rectifier 102, a first stage converter 104, and a second stage converter 106.

The voltage doubler rectifier 102 can have a switch 108. The voltage doubler rectifier 102 can be configured to rectify a received voltage in response to the switch 108 being in a first position. For example, the voltage doubler rectifier 102 can be configured to rectify a received voltage in response to the switch being in an opened position. The voltage doubler rectifier 102 can be configured to rectify and effectively double a received voltage in response to the switch 108 being in a second position. For example, the voltage doubler rectifier 102 can be configured to rectify and effectively double a received voltage in response to the switch being in a closed position. The phrase “effectively double a received voltage” can be understood to mean that a magnitude of the effectively doubled received voltage is closer to a product of the absolute value of the received voltage multiplied by two than to the absolute value of the received voltage.

In an implementation, the voltage doubler rectifier 102 can include, for example, a diode 110, a diode 112, a diode 114, a diode 116, a capacitor 118, a capacitor 120, and the switch 108. A cathode of the diode 110 can be connected to a node 122. An anode of the diode 110 can be connected to a node 124. A cathode of the diode 112 can be connected to the node 122. An anode of the diode 112 can be connected to a node 126. A cathode of the diode 114 can be connected to the node 124. An anode of the diode 114 connected to a node 128. A cathode of the diode 116 can be connected to the node 126. An anode of the diode 116 can be connected to the node 128. The capacitor 118 can be coupled between the node 122 and a node 130. The capacitor 120 can be coupled between the node 128 and the node 130. The switch 108 can be coupled between the node 126 and the node 130. The voltage double rectifier 102 can be connected to a ground 132. For example, the node 128 can be connected to the ground 132. For example, the ground 132 can be a signal ground.

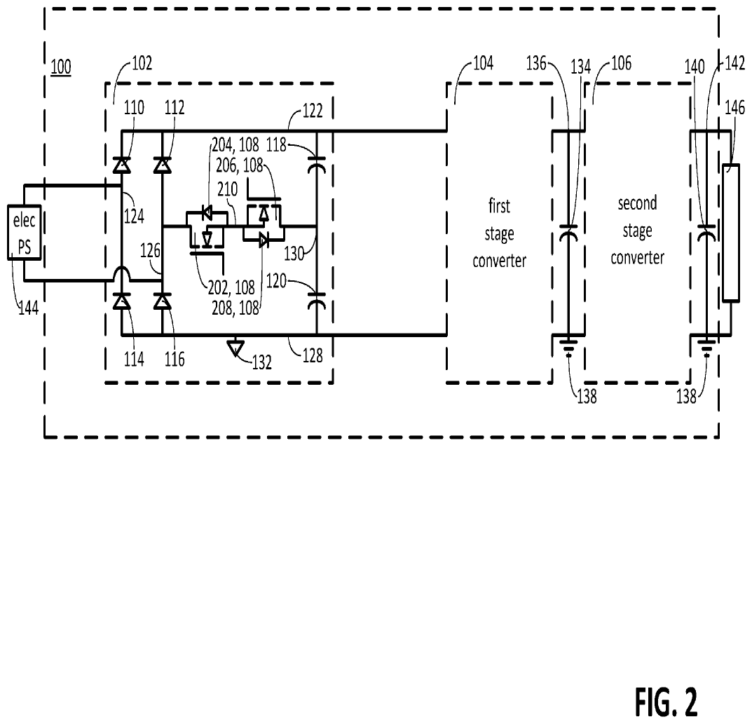

The switch 108 can include, for example, a relay, a microelectromechanical (MEMS) switch, a triac, a transistor, the like, or any combination thereof If the switch 108 includes a transistor, then the transistor can be, for example, a bipolar junction transistor (BJT), a junction gate field-effect transistor (JFET), a metal-oxide-semiconductor field-effect transistor (MOSFET), the like, or any combination thereof In an implementation, the switch 108 can include an n-channel enhancement type MOSFET 202, a diode 204, an n-channel enhancement type MOSFET 206, and a diode 308 as illustrated in FIG. 2. A cathode of the diode 204 can be connected to a drain of the n-channel enhancement type MOSFET 202. An anode of the diode 204 can be connected to a source of the n-channel enhancement type MOSFET 202. A cathode of the diode 208 can be connected to a drain of the n-channel enhancement type MOSFET 206. An anode of the diode 208 can be connected to a source of the n-channel enhancement type MOSFET 206. The source of the n-channel enhancement type MOSFET 202 can be connected to a node 210. The source of the n-channel enhancement type MOSFET 206 can be connected to the node 210.

Returning to FIG. 1, the first stage converter 104 can be coupled to the voltage doubler rectifier 102. The first stage converter 104 can be a first type of converter. The first type of converter can be either an isolated converter or a non-isolated converter. An isolated converter can include, for example, an LLC converter, an LCC converter, a flyback converter, a half-bridge converter, a full-bridge converter, a silicon controlled rectifier converter, a resonant converter, a parallel resonant converter, or the like. A non-isolated converter can include, for example, a buck-boost converter, a buck converter, a boost converter, or the like.

The second stage converter 106 can be coupled to the first stage converter 104. The second stage converter 106 can be a second type of converter. The second type of converter can be either the isolated converter or the non-isolated converter. The second type of converter can be different from the first type of converter.

A capacitor 134 can represent integral capacitance between the first stage converter 104 and the second stage converter 106. The capacitor 134 can be connected to an output 136 of the first stage converter 104. The capacitor 134 can be configured to be connected to a ground 138. The ground 138 can be different from the ground 132. For example, the ground 138 can be an earth ground.

A capacitor 140 can represent output capacitance of the adapter 100. The capacitor 140 can be can be connected to an output 142 of the adapter 100. The capacitor 140 can be configured to be connected to the ground 138.

The adapter 100 can be configured to be connected to an electrical power supply 144. For example, the electrical power supply 144 can be an alternating current power supply or a direct current power supply.

The adapter 100 can be configured to be connected to a load 146. For example, the load 146 can be a portable electronic device, a mobile electronic device, or the like.

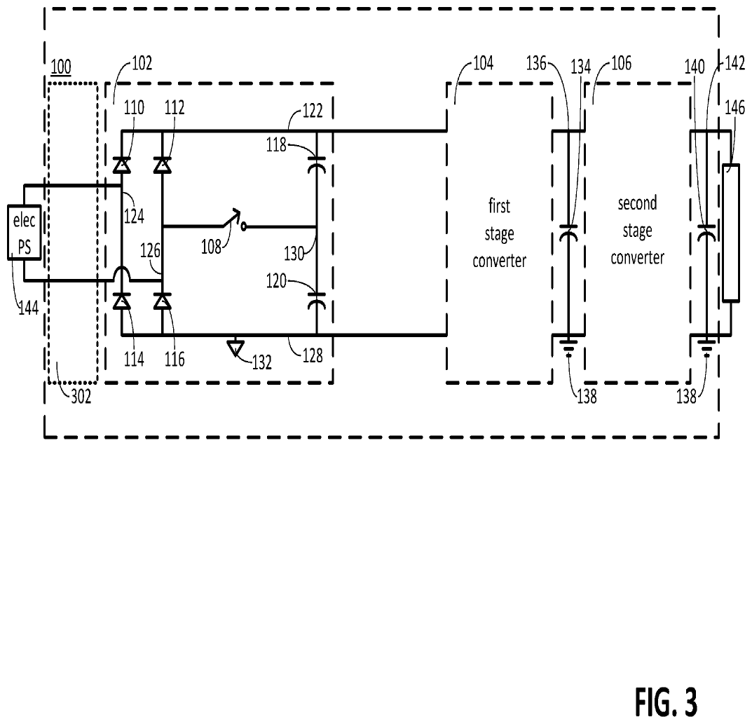

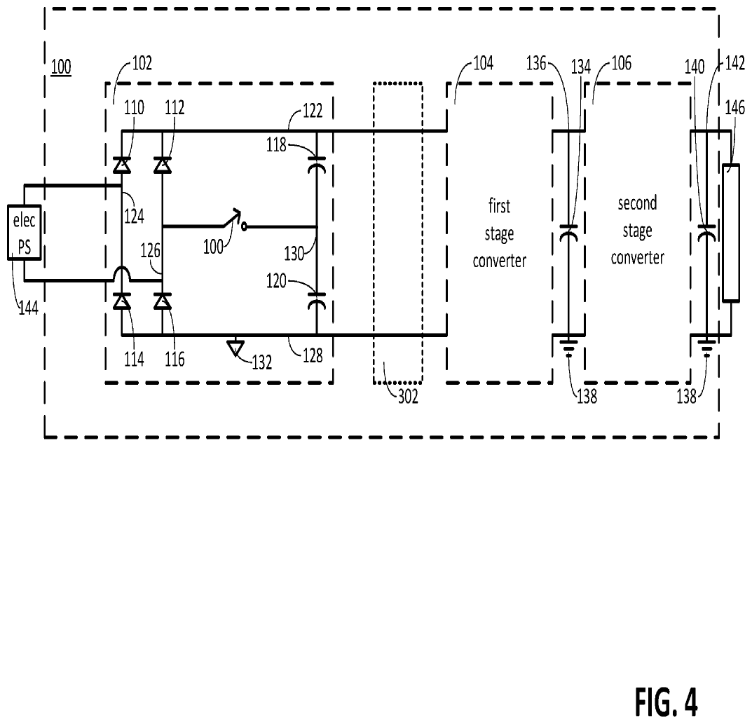

Optionally, as illustrated in FIG. 3, the adapter 100 can further include a filter 302 coupled to the voltage doubler rectifier 102. In an implementation, the filter 302 can be coupled between the electrical power supply 144 and the voltage doubler rectifier 102. In another implementation, the filter 302 can be coupled between the voltage doubler rectifier 102 and the first stage converter 104 as illustrated in FIG. 4. The filter 302 can be configured to filter a signal for one or more portions of the signal that can cause electromagnetic interference during processing of the signal subsequent to having been filtered.

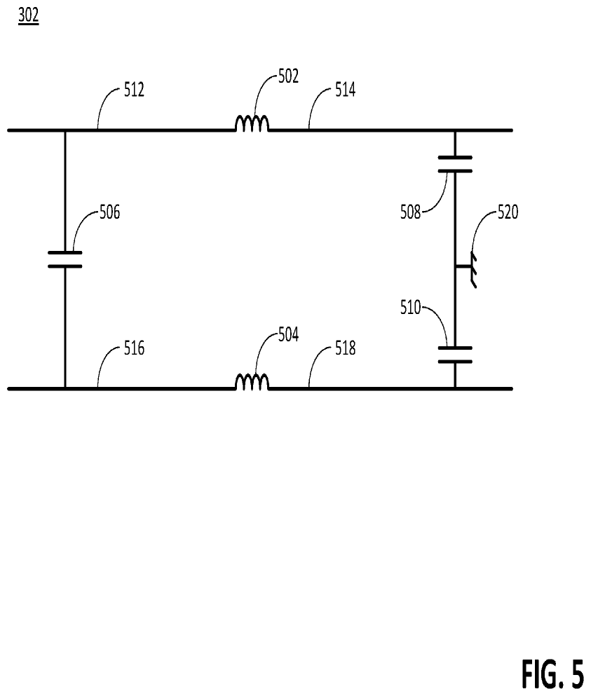

FIG. 5 is a block diagram of an example of the filter 302 illustrated in FIGS. 3 and 4. The filter 302 can include, for example, an inductor 502, an inductor 504, a capacitor 506, a capacitor 508, and a capacitor 510. The inductor 502 can be coupled between a node 512 and a node 514. The inductor 504 can be coupled between a node 516 and a node 518. The capacitor 506 can be coupled between the node 512 and the node 516. The capacitor 508 can be coupled between the node 514 and a ground 520. The capacitor 510 can be coupled between the node 518 and the ground 520. The ground 520 can be different from the ground 132 and the ground 138. For example, the ground 520 can be a chassis ground. In the implementation illustrated in FIG. 3, the node 514 can be the node 124, and the node 518 can be the node 126. In the implementation illustrated in FIG. 4, the node 512 can be the node 122, and the node 516 can be the node 128.

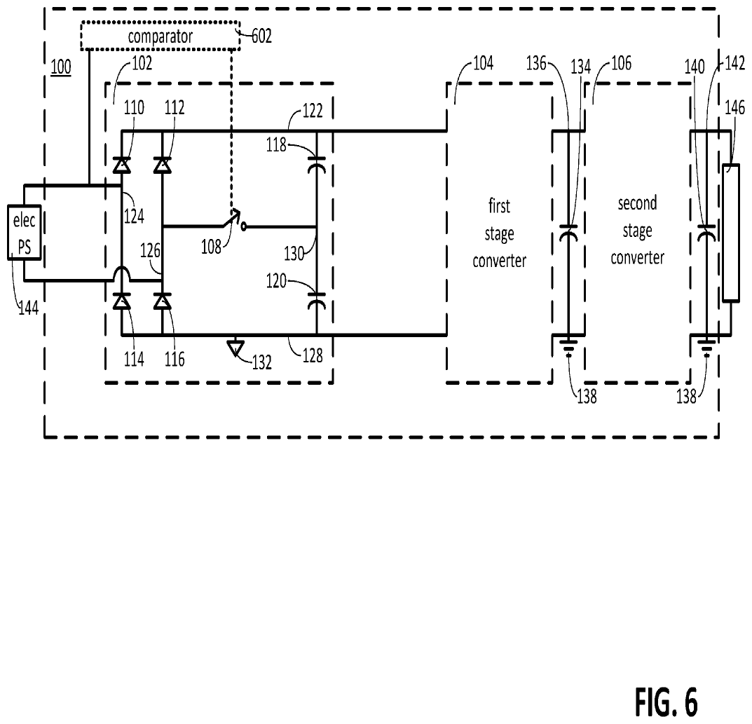

FIG. 6 is a block diagram of an example implementation of the adapter 100 in which the adapter 100 can further include a comparator 602. The comparator 602 can be configured to compare a voltage of the electrical power supply 144 (e.g., as measured at the node 124) with a threshold voltage. The comparator 602 can be configured to produce, in response to a result of a comparison of the voltage of the electrical power supply 144 with the threshold voltage, a signal to control a position of the switch 108. For example, if the threshold voltage is 170 volts and the voltage of the electrical power supply 144 is 220 volts (i.e., the voltage supplied to wall sockets for most of the world), then the comparator 602 can produce a signal to cause the switch 108 to be in an opened position. For example, if the threshold voltage is 170 volts and the voltage of the electrical power supply 144 is 120 volts (i.e., the voltage supplied to wall sockets in the Americas), then the comparator 602 can produce a signal to cause the switch 108 to be in a closed position.

With the switch 108 being in an opened position, in response to the voltage doubler rectifier 102 receiving: (1) a positive half cycle of an alternating current power supply from the electrical power supply 144, both the capacitor 118 and the capacitor 120 can be charged through the diode 110 and (2) a negative half cycle of the alternating current power supply from the electrical power supply 144, both the capacitor 118 and the capacitor 120 can be charged through the diode 112. In this manner, a voltage at the node 122 can be rectified with an absolute value of a magnitude close to an absolute value of a peak voltage of a half cycle of the alternating current power supply from the electrical power supply 144.

With the switch 108 being in a closed position, in response to the voltage doubler rectifier 102 receiving: (1) a positive half cycle of an alternating current power supply from the electrical power supply 144, the capacitor 118 can be charged through the diode 110 and (2) a negative half cycle of the alternating current power supply from the electrical power supply 144, the capacitor 120 can be charged through the switch 108. In this manner, a voltage at the node 122 can be rectified with an absolute value of a magnitude effectively double an absolute value of a peak voltage of a half cycle of the alternating current power supply from the electrical power supply 144 (i.e., the voltage of the charge stored in the capacitor 118 added to the voltage of the charge stored in the capacitor 120).

In this manner, the adapter 100 can be configured to function whether the voltage of the electrical power supply 144 is a high voltage (e.g., 220 volts) or a low voltage (e.g., 120 volts).

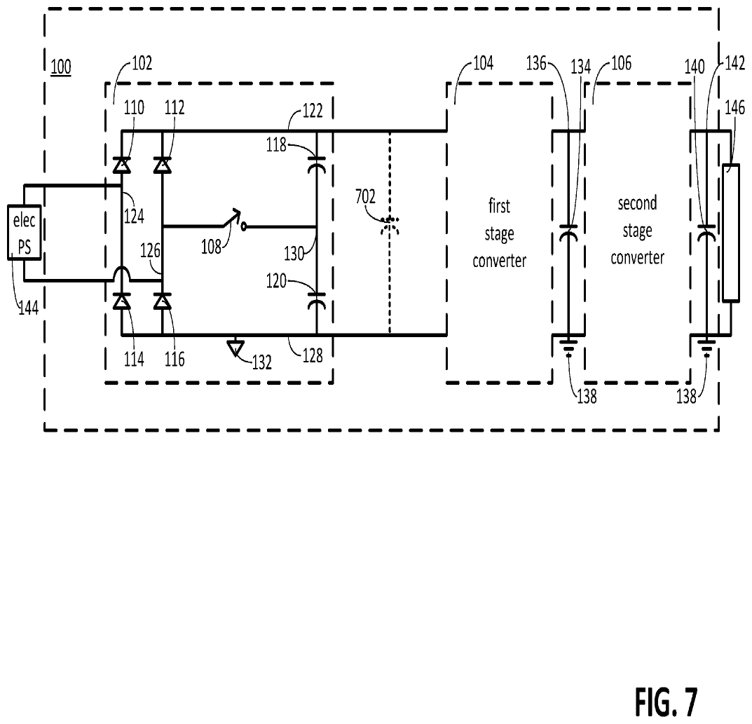

FIG. 7 is a block diagram of an example implementation of the adapter 100 in which the adapter 100 can further include a bulk capacitor 702. In the implementation illustrated in FIGS. 1 and 3, the bulk capacitor 702 can be coupled between the node 122 and the node 128. In the implementation illustrated in FIG. 4, the bulk capacitor 702 can be coupled between the node 512 and the node 516 or between the node 514 and the node 518.

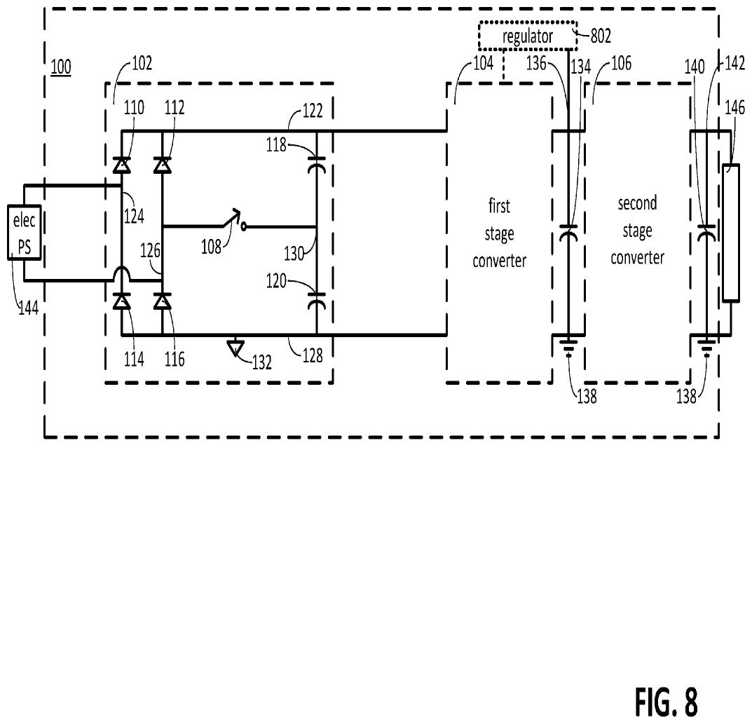

FIG. 8 is a block diagram of an example implementation of the adapter 100 in which the adapter 100 can further include a regulator 802 for the first stage converter 104. The regulator 802 can be configured to control an operation of the first stage converter 104 to maintain a voltage at the output 136 of the first stage converter 104 within a range of voltages. In an implementation, the regulator 802 can be configured to control, in response to the voltage at the output 136 being less than a threshold voltage, the operation of the first stage converter 104 to maintain the voltage at the output 136 within the range of voltages.

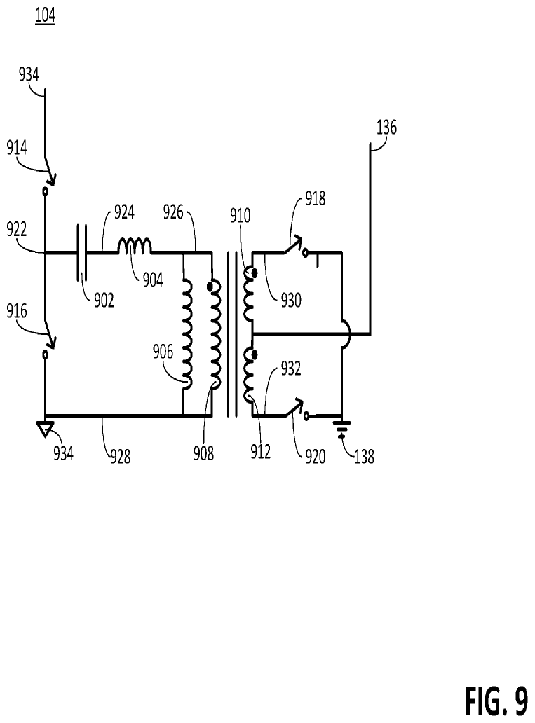

FIG. 9 is a block diagram of an example of the first stage converter 104. The first stage converter 104 can include, for example, a capacitor 902, an inductor 904, an inductor 906, a primary winding 908 of a transformer, a secondary winding 910 of the transformer, a secondary winding 912 of the transformer, a switch 914, a switch 916, a switch 918, and a switch 920. The capacitor 902 can be coupled between a node 922 and a node 924. The inductor 904 can be coupled between the node 924 and a node 926. The inductor 906 can be coupled between the node 926 and a node 928. The primary winding 908 can be coupled between the node 926 and the node 928. The secondary winding 910 can be coupled between a node 930 and the node 136. The secondary winding 912 can be coupled between a node 932 and the node 136. The switch 914 can be coupled between a node 934 and the node 922. The switch 916 can be coupled between the node 928 and the node 922. The switch 918 can be coupled to the node 930 and can be configured to be connected to the ground 138. The switch 920 can be coupled to the node 932 and can be configured to be connected to the ground 138. The node 928 can be connected to a ground 934. In the implementations illustrated in FIGS. 1 and 3, the node 934 can be the node 122, the node 928 can be the node 128, and the ground 934 can be the ground 132. In the implementation illustrated in FIG. 4, the node 934 can be the node 514, the node 928 can be the node 518, and the ground 934 can be different from the ground 132, the ground 138, and the ground 520. For example, the ground 934 can be a signal ground. Because the primary winding 908 is coupled to the ground 934 through the node 928 and the secondary winding 910 and the secondary winding 912 are configured to be coupled to the ground 138, respectively, through the switch 918 and the switch 920, the transformer can provide the first stage converter 104 with galvanic isolation.

During a positive half cycle of an alternating current power supply from the electrical power supply 144, the switches 914 and 918 can be in a closed position, and the switches 916 and 920 can be in an opened position. The voltage at the node 934 can cause a current to flow through the capacitor 902, the inductor 904, the inductor 908, and the primary winding 908. A charge can be stored by the capacitor 902 so that a voltage drop across the capacitor 902 can be equal to the voltage at the node 934. The capacitor 902, the inductor 904, and the inductor 908 can act as a voltage divider so that the voltage at the node 926 is less than the voltage at the node 934. Additionally, the current that flows through the primary winding 908 can induce a current to flow through the secondary winding 910. The voltage at the node 136 can be a product of the voltage at the node 926 multiplied by a quotient. The quotient can be the number of turns of the secondary winding 910 divided by the number of turns of the primary winding 908.

During a negative half cycle of an alternating current power supply from the electrical power supply 144, the switches 916 and 920 can be in a closed position, and the switches 914 and 918 can be in an opened position. The charge stored by the capacitor 902 can discharge to the ground 934 and can cause a current to flow through the capacitor 902, the inductor 904, the inductor 908, and the primary winding 908. The capacitor 902, the inductor 904, and the inductor 908 can act as a voltage divider so that the voltage at the node 926 is less than the voltage drop across the capacitor 902. Additionally, the current that flows through the primary winding 908 can induce a current to flow through the secondary winding 912. The voltage at the node 136 can be a product of the voltage at the node 926 multiplied by a quotient. The quotient can be the number of turns of the secondary winding 912 divided by the number of turns of the primary winding 908.

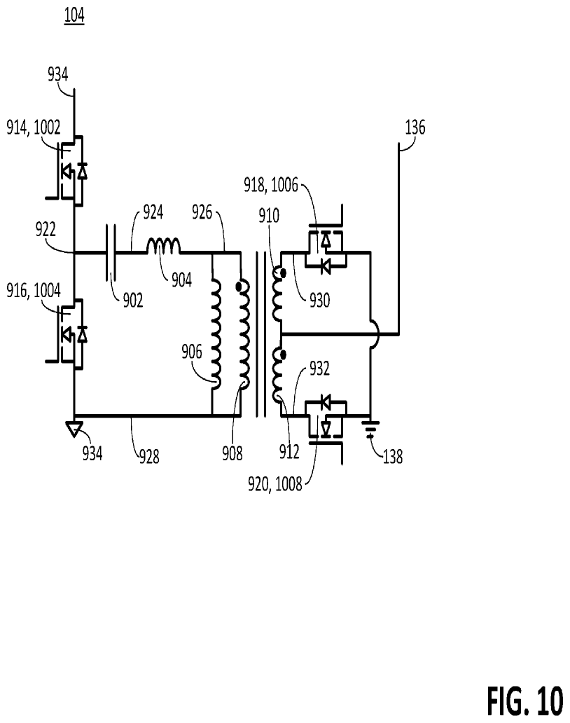

One or more of the switches 914, 916, 918, and 920 can include, for example, a relay, a microelectromechanical (MEMS) switch, a triac, a transistor, the like, or any combination thereof. If one or more of the switches 914, 916, 918, and 920 includes a transistor, then the transistor can be, for example, a bipolar junction transistor (BJT), a junction gate field-effect transistor (JFET), a metal-oxide-semiconductor field-effect transistor (MOSFET), the like, or any combination thereof. In an implementation, one or more of the switches 914, 916, 918, and 920 can include an n-channel enhancement type MOSFET and a diode. A cathode of the diode can be connected to a drain of the n-channel enhancement type MOSFET. An anode of the diode can be connected to a source of the n-channel enhancement type MOSFET. FIG. 10 is a block diagram of an example of the first stage converter 104 in which each of the switches 914, 916, 918, and 920 can include a parallel connection of a transistor and a diode. The switch 914 can include a parallel connection of an n-channel enhancement type MOSFET and a diode 1002. The switch 916 can include a parallel connection of an n-channel enhancement type MOSFET and a diode 1004. The switch 918 can include a parallel connection of an n-channel enhancement type MOSFET and a diode 1006. The switch 920 can include a parallel connection of an n-channel enhancement type MOSFET and a diode 1008.

The first stage converter 104 can be configured to operate close to a resonant frequency. This can reduce the reactance portion of the impedance of the adapter 100. The resonant frequency can be determined from a value of the capacitance of the capacitor 902, a value of the inductance of the inductor 904, and a value of the inductance of the inductor 906. One or more of the switches 914, 916, 918, and 920 can be configured to be controlled by one or more signals. The one or more signals can have a duty cycle of fifty percent. However, in an implementation in which the adapter 100 includes the regulator 802 for the first stage converter 104, the regulator 802 can adjust the duty cycle to maintain the voltage at the output 136 within the range of voltages. The first stage converter 104 can be configured to be operated to achieve zero voltage switching for the switches 914 and 916. The first stage converter 104 can be configured to be operated to achieve zero current switching for the switches 918 and 920.

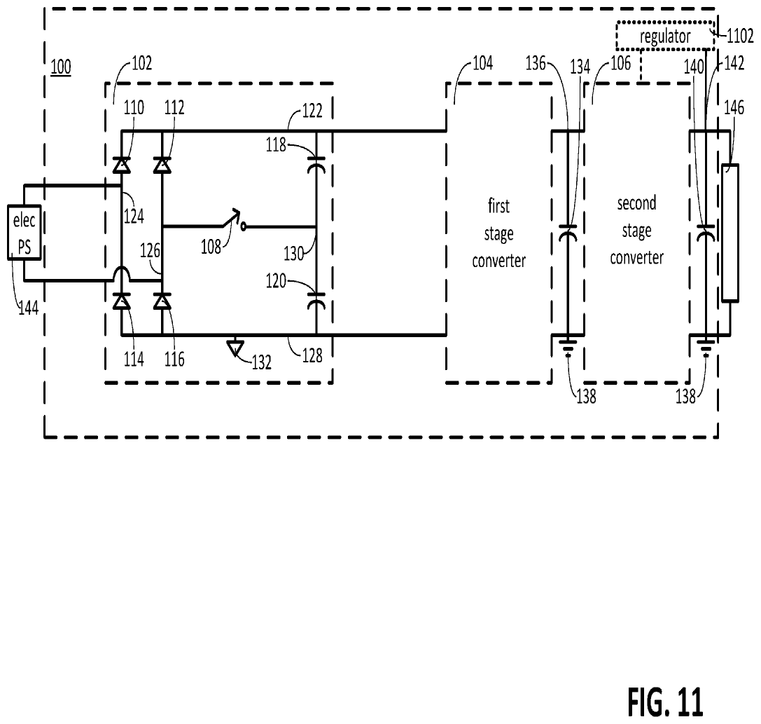

FIG. 11 is a block diagram of an example implementation of the adapter 100 in which the adapter 100 can further include a regulator 1102 for the second stage converter 106. The regulator 1102 can be configured to control an operation of the second stage converter 106 to maintain a voltage at the output 142 of the adapter 100 within a range of voltages. In an implementation, the regulator 1102 can be configured to control, in response to the voltage at the output 142 being less than a threshold voltage, the operation of the second stage converter 106 to maintain the voltage at the output 142 within the range of voltages.

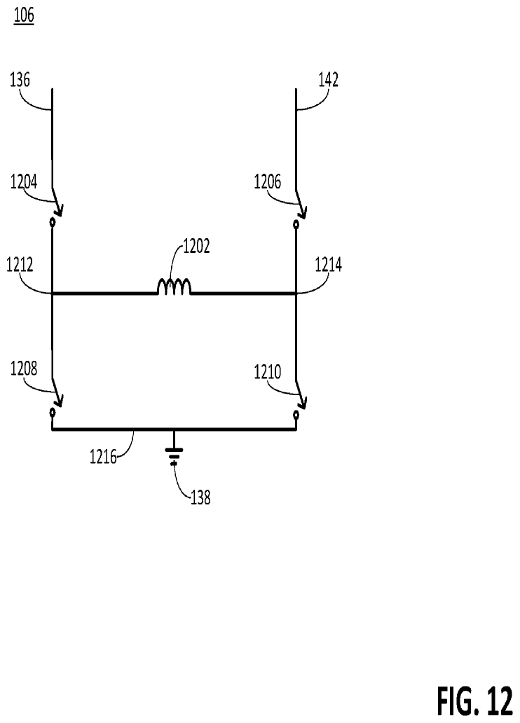

FIG. 12 is a block diagram of an example of the second stage converter 106. The second stage converter 106 can include, for example, an inductor 1202, a switch 1204, a switch 1206, a switch 1208, and a switch 1210. The inductor 1202 can be coupled between a node 1212 and a node 1214. The switch 1204 can be coupled between the node 1212 and the node 136. The node 136 can be the output of the first stage converter 104. The switch 1206 can be coupled between the node 1214 and the node 142. The node 142 can be the output of the adapter 100. The switch 1208 can be coupled between the node 1212 and a node 1216. The switch 1210 can be coupled between the node 1214 and the node 1216. The node 1216 can be configured to be connected to the ground 138.

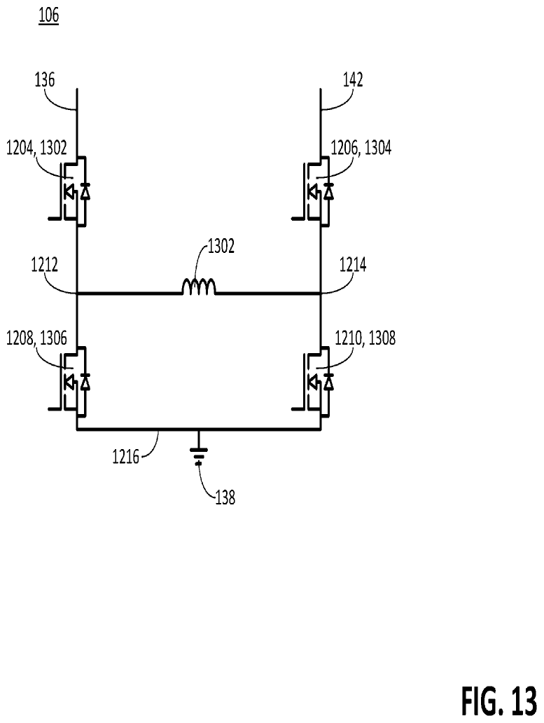

One or more of the switches 1204, 1206, 1208, and 1210 can include, for example, a relay, a microelectromechanical (MEMS) switch, a triac, a transistor, the like, or any combination thereof If one or more of the switches 1204, 1206, 1208, and 1210 includes a transistor, then the transistor can be, for example, a bipolar junction transistor (BJT), a junction gate field-effect transistor (JFET), a metal-oxide-semiconductor field-effect transistor (MOSFET), the like, or any combination thereof. In an implementation, one or more of the switches 1204, 1206, 1208, and 1210 can include an n-channel enhancement type MOSFET and a diode. A cathode of the diode can be connected to a drain of the n-channel enhancement type MOSFET. An anode of the diode can be connected to a source of the n-channel enhancement type MOSFET. FIG. 13 is a block diagram of an example of the second stage converter 106 in which each of the switches 1204, 1206, 1208, and 1210 can include a parallel connection of a transistor and a diode. The switch 1204 can include a parallel connection of an n-channel enhancement type MOSFET and a diode 1302. The switch 1206 can include a parallel connection of an n-channel enhancement type MOSFET and a diode 1304. The switch 1208 can include a parallel connection of an n-channel enhancement type MOSFET and a diode 1306. The switch 1210 can include a parallel connection of an n-channel enhancement type MOSFET and a diode 1308.

One or more of the switches 1204, 1206, 1208, and 1210 can be configured to be controlled by one or more signals. The one or more signals can have one or more adjustable duty cycles. Furthermore, in an implementation in which the adapter 100 includes the regulator 1102 for the second stage converter 106, the regulator 1102 can adjust the one or more duty cycles to maintain the voltage at the output 142 within the range of voltages.

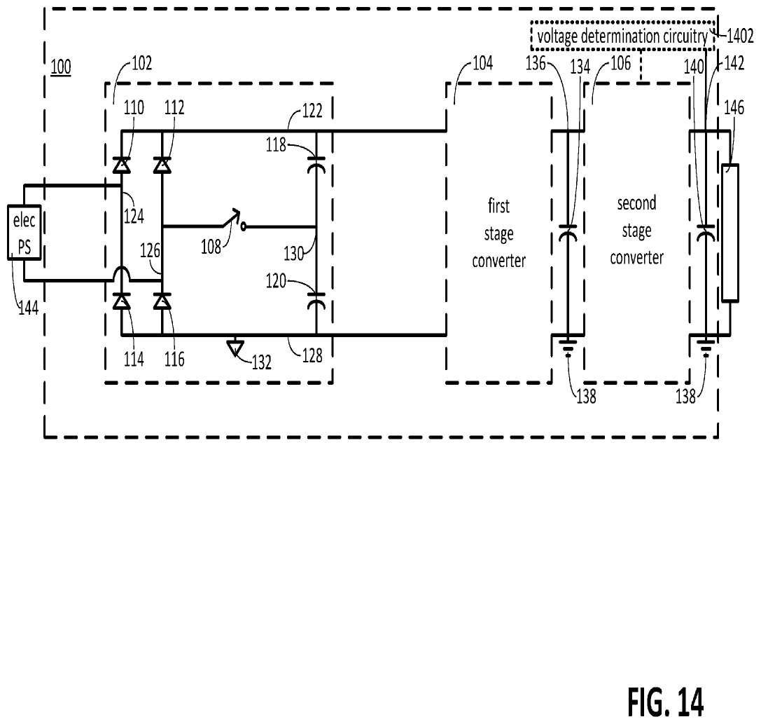

FIG. 14 is a block diagram of an example implementation of the adapter 100 in which the adapter 100 can further include voltage determination circuitry 1402. The voltage determination circuitry 1402 can be configured to determine, in response to the load 146 being connected to the adapter 100, a voltage rating of a battery of the load 146. For example, the voltage determination circuitry 1402 can be configured to determine the voltage rating by receiving a signal from a Universal Serial Bus™ connector used to connect the load 146 to the adapter 100. Additionally or alternatively, for example, the voltage determination circuitry 1402 can be configured to determine the voltage rating by comparing a voltage of the load 146 (e.g., as measured at the node 142) with one or more threshold voltages. The voltage determination circuitry 1402 can be configured to determine, in response to a result of a determination of the voltage rating, one or more specific duty cycles to cause a voltage at the output 142 to match the voltage rating. The voltage determination circuitry 1402 can be configured to produce, in response to a determination of the one or more specific duty cycles, the one or more signals to control the one or more of the switches 1204, 1206, 1208, and 1210. The one or more signals can have the one or more specific duty cycles.

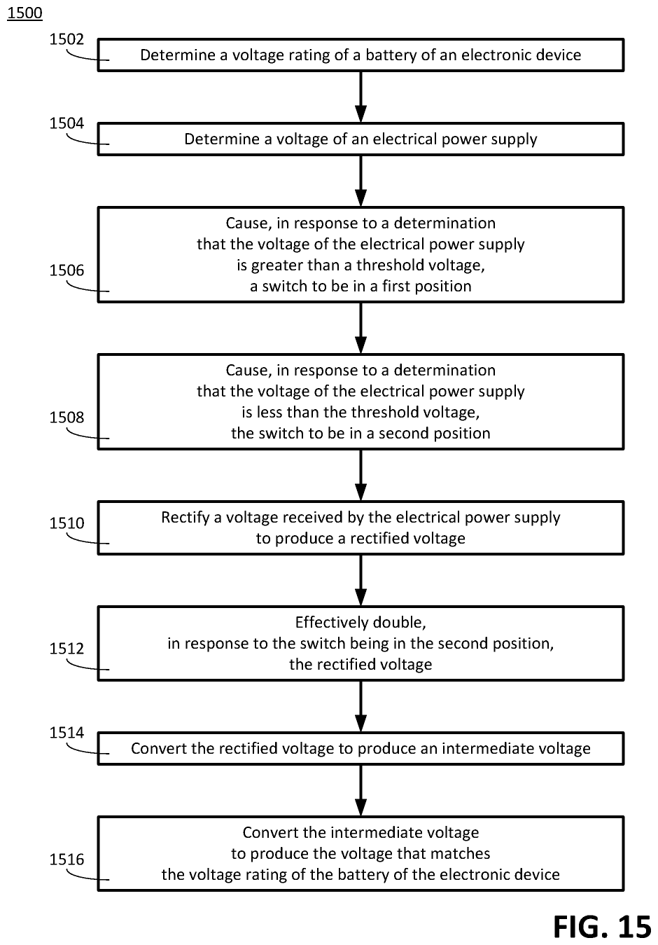

FIG. 15 is a flow diagram of an example of a method 1500 for producing, from a voltage of an electrical power supply, a voltage that matches a voltage rating of a battery of an electronic device, according to the disclosed technologies. In the method 1500, at an operation 1502, the voltage rating of the battery of the electronic device can be determined by a circuit. The electronic device can be separate from the circuit, but can be connected to the circuit.

At an operation 1504, the voltage of the electrical power supply can be determined by the circuit. The electrical power supply can be separate from the circuit, but can be connected to the circuit.

At an operation 1506, in response to a determination that the voltage of the electrical power supply is greater than a threshold voltage, a switch can be caused, by the circuit, to be in a first position.

At an operation 1508, in response to a determination that the voltage of the electrical power supply is less than the threshold voltage, the switch can be caused, by the circuit, to be in a second position.

At an operation 1510, a voltage received by the electrical power supply can be rectified, by the circuit, to produce a rectified voltage.

At an operation 1512, in response to the switch being in the second position, the rectified voltage can be effectively doubled by the circuit.

At an operation 1514, the rectified voltage can be converted, by a first stage of the circuit, to produce an intermediate voltage.

At an operation 1516, the intermediate voltage can be converted, by a second stage of the circuit, to produce the voltage that matches the voltage rating of the battery of the electronic device.

The first stage can be a first type. The first type can be one of a type that includes galvanic isolation or a type that lacks galvanic isolation. The second stage can be a second type. The second type can be one of the type that includes galvanic isolation or the type that lacks galvanic isolation. The second type can be different from the first type.

In general, in light of the technologies described above, one of skill in the art understands that technologies to produce, from a voltage of an electrical power supply, a voltage that matches a voltage rating of a battery of an electronic device can include any combination of some or all of the foregoing configurations.

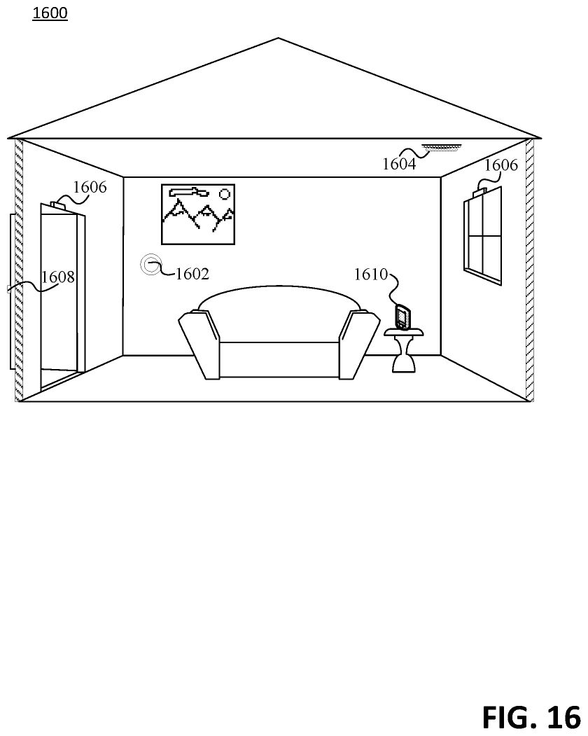

FIG. 16 is a diagram of an example environment 1600 for a security system integrated in a smart home environment that can include sensors, interface components, and one or more processing units that process data generated by the sensors and that control the interface components. Data from the sensors can be used to determine the occurrence of a security breach or security related event, such as entry through a window of the premises, lengthy presence of an individual in an unusual location and an unusual time, or tampering with a lock of a door of the premises, etc. Upon the occurrence of such an event, the security system can determine, based on any of various algorithms, that an alarm is warranted and enter into an alarm mode, which can include automatically notifying a third party monitoring service as well as operating components of the system to provide visual and/or audible alerts, such as a siren sound, repeated beeping sound, or flashing lights.

Additionally, the security system can determine where a security breach has occurred and thereafter track the location of the unauthorized party, as well as the locations of authorized parties within and/or around the premises. Additionally, in view of the high stress levels that can accompany experiencing an unauthorized intrusion, the security system can announce the location of the security breach and the location of the unauthorized party within the premises. In so doing the authorized occupants are automatically warned of which locations in/around the premises to avoid and the unauthorized party is simultaneously deterred from further advance due to the clear notice to the unauthorized party that he/she is being tracked. Alternatively, the location of the unauthorized party can be announced only to select devices so as to inform an authorized user while leaving the unauthorized party unaware that he/she is being tracked.

The security system can function as a subsystem of a smart facility network system and can incorporate a plurality of electrical and/or mechanical components, including intelligent, sensing, network-connected devices that can communicate with each other and/or can communicate with a central server or a cloud-computing system to provide any of a variety of security (and/or environment) management objectives in a home, office, building or the like. Such objectives, which can include, for example, managing alarms, notifying third parties of alarm situations, managing door locks, monitoring the premises, etc., herein are collectively referred to as “premises management.”

A premises management system can further include other subsystems that can communicate with each other to manage different aspects of premises management as well as security. For example, a security subsystem can manage the arming, disarming, and activation of alarms and other security aspects of the premises, and a smart home environment subsystem can handle aspects such as light, temperature, and hazard detection of the premises. However, the premises management system can leverage data obtained in one subsystem to improve the functionality of another subsystem.

The security system can be operable to function in any of various modes or states. For example, security system modes can include “stay”, “away” and “home” modes. In a “stay” mode the security system can operate under the assumption that authorized parties are present within the premises but will not be entering/leaving without notifying the system; therefore data from certain interior sensors can be given lower weight in determining whether an unauthorized party is present. In an “away” mode the security system can operate under the assumption that no authorized parties are in the premises; therefore data from all sensors, interior and exterior, can be accorded high weight in determining whether an unauthorized party is present. In a “home” mode the security system can operate under the assumption that authorized parties are within the premises and will be freely entering/leaving the premises without notifying the system; therefore data from certain sensors interior and exterior can be accorded low weight in determining whether an unauthorized party is present. It should be understood that these modes are merely examples and can be modified, removed, or supplemented by other modes.

Additionally, the security system can function in any of various alarm states. For example, in a “green” or “low” alarm state the security system can operate under the assumption that all is well and no unauthorized parties have been detected within/around the premises. In a “yellow” or “medium” alarm state the security system can operate under the assumption that an unauthorized party is potentially present in or around the premises. In this state certain sensor data can be analyzed differently or additional confirmations of authorization, such as entering a code, can be required of to avoid escalation to a higher alarm state. In a “red” or “high” alarm state the security system can operate under the assumption that an unauthorized party has been detected on the premises and preventive measures can be taken, such as notifying a third party monitoring service and/or activating an alarm and announcement, as will be described later. It should be understood that greater or fewer gradients of alarm state can be included. Hereinafter, a heightened alarm can refer to an alarm state above the low alarm state.

The security system can be implemented as a stand-alone system or, as mentioned above, as a subsystem of a larger premises management system and can leverage data therefrom. For illustrative purposes and to demonstrate the cross use of data among systems, the security system can be part of a premises management system, such as a smart home network environment.

The individual hardware components of the premises management system that can be used to monitor and affect the premises in order to carry out premises management can be referred to as “premises management devices.” The premises management devices described herein can include multiple physical hardware and firmware configurations, along with circuitry hardware (e.g., processors, memory, etc.), firmware, and software programming that are configured to carry out the methods and functions of a premises management system. The premises management devices can be controlled by a “brain” component, which can be implemented in a controller device.

The system 1600 can implement subsystems, including the security system, via multiple types of premises management devices, such as one or more intelligent, multi-sensing, network-connected thermostats 1602, one or more intelligent, multi-sensing, network-connected hazard detection units 1604, one or more intelligent, multi-sensing, network-connected entry detection units 1606, one or more network-connected door handles 1608, one or more intelligent, multi-sensing, network-connected controller devices 1610, or any combination thereof. Data from any of these premise management devices can be used by the security system, as well as for the respective primary functions of the premise management devices.

At a high level, the system 1600 can be configured to operate as a learning, evolving ecosystem of interconnected devices. New premises management devices can be added, introducing new functionality, expanding existing functionality, or expanding a spatial range of coverage of the system. Furthermore, existing premises management devices can be replaced or removed without causing a failure of the system 1600. Such removal can encompass intentional or unintentional removal of components from the system 1600 by an authorized user, as well as removal by malfunction (e.g., loss of power, destruction by intruder, etc.). Due to the dynamic nature of the system, the overall capability, functionality and objectives of the system 1600 can change as the constitution and configuration of the system 1600 change.

In order to avoid contention and race conditions among the interconnected devices, certain decisions, such as those that affect the premises management system 1600 at a system level or that involve data from multiple sources, can be centralized in the aforementioned “brain” component. The brain component can coordinate decision making across the system 1600 or across a designated portion thereof. The brain component is a system element at which, for example, sensor/detector states can converge, user interaction can be interpreted, sensor data can be received, and decisions can be made concerning the state, mode, or actions of the system 1600. Hereinafter, the system 1600 brain component can be referred to as the “primary system processor.” The function of primary system processor can be implemented in the controller device 1610, for example, hard coded into a single device, or distributed virtually among one or more premises management devices within the system using computational load sharing, time division, shared storage, or other techniques.

However implemented, the primary system processor can be configured to control subsystems and components of the premises management system 1600, such as, for example, the disclosed security system and/or a smart home environment system. Furthermore, the primary system processor can be communicatively connected to control, receive data from, or transmit data to premises management devices within the system, as well as receive data from or transmit data to devices/systems external to the system 1600, such as third party servers, cloud servers, mobile devices, and the like.

In the embodiments disclosed herein, each of the premises management devices can include one or more sensors. In general, a “sensor” can refer to any device that can obtain information about its local environment and communicate that information in the form of data that can be stored or accessed by other devices and/or systems. Sensor data can form the basis of inferences drawn about the sensor's environment. For example, the primary system processor can use data from a plurality of sensors, e.g., including entry detection unit 1606, to determine whether an unauthorized party is attempting enter the house through a window.

A brief description of sensors that may be included in the system 1600 follows. Examples provided are not intended to be limiting but are merely provided as illustrative subjects. The system 1600 can use data from the types of sensors in order to implement features of a security system. The system 1600 can employ data from any type of sensor that provides data from which an inference can be drawn about the environment in or around the house.

Generally, sensors can be described by the type of information they collect. For example, sensor types can include motion, smoke, carbon monoxide, proximity, temperature, time, physical orientation, acceleration, location, entry, presence, pressure, light, sound, and the like. A sensor also can be described in terms of the particular physical device that obtains the environmental information. For example, an accelerometer can obtain acceleration information, and thus can be used as a general motion sensor and/or an acceleration sensor. A sensor also can be described in terms of the specific hardware components used to implement the sensor. For example, a temperature sensor can include a thermistor, thermocouple, resistance temperature detector, integrated circuit temperature detector, or combinations thereof.

A sensor further can be described in terms of a function or functions the sensor performs within the system 1600. For example, a sensor can be described as a security sensor when it is used to determine security events, such as unauthorized entry.

A sensor can be operated for different functions at different times. For example, system 1600 can use data from a motion sensor to determine how to control lighting in the house when an authorized party is present and use the data as a factor to change a security system mode or state on the basis of unexpected movement when no authorized party is present. In another example, the system 1600 can use the motion sensor data differently when a security system mode is in an “away” mode versus a “home” state, i.e., certain motion sensor data can be ignored while the system is in a “home” mode and acted upon when the system is in an “away” mode.

In some cases, a sensor can operate as multiple sensor types sequentially or concurrently, such as where a temperature sensor is used to detect a change in temperature, as well as the presence of a person or animal. A sensor also can operate in different modes (e.g., different sensitivity or threshold settings) at the same or different times. For example, a sensor can be configured to operate in one mode during the day and another mode at night. As another example, a sensor can operate in different modes based upon a mode or the disclosed security system, state of system 1600, or as otherwise directed by the primary system processor.

Multiple sensors can be arranged in a single physical housing, such as where a single device includes movement, temperature, magnetic, and/or other sensors. Such a housing can also be referred to as a sensor, premises management device, or a sensor device. For clarity, sensors can be described with respect to the particular functions they perform and/or the particular physical hardware used.

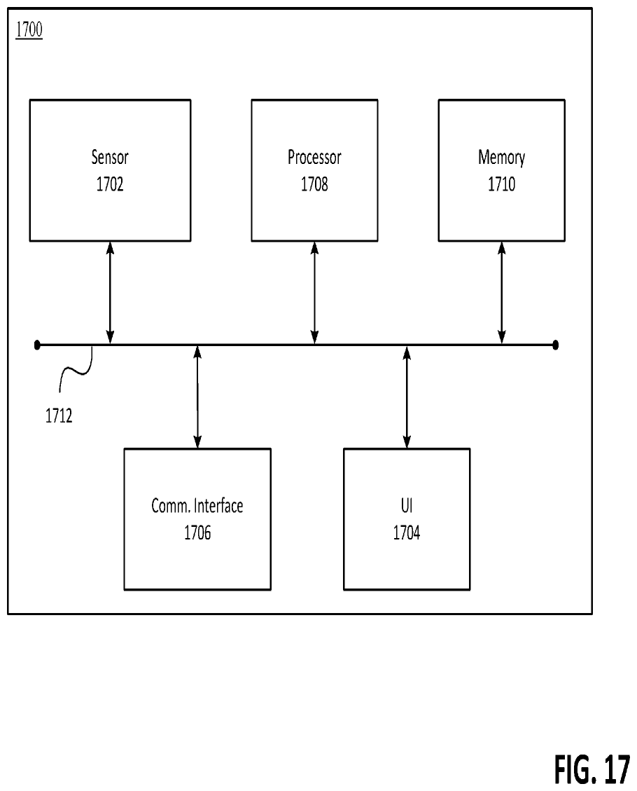

FIG. 17 is a block diagram of an example of an embodiment of a premises management device 1700. Premise management device 1700 can include a processor 1708, a memory 1710, a user interface (UI) 1704, a communications interface 1706, an internal bus 1712, and a sensor 1702. A person of ordinary skill in the art appreciates that various components of the premises management device 1700 described herein can include additional electrical circuit(s). Furthermore, it is appreciated that many of the various components listed above can be implemented on one or more integrated circuit (IC) chips. For example, in one embodiment, a set of components can be implemented in a single IC chip. In other embodiments, one or more of respective components can be fabricated or implemented on separate IC chips.

The sensor 1702 can be an environmental sensor, such as a temperature sensor, smoke sensor, carbon monoxide sensor, motion sensor, accelerometer, proximity sensor, passive infrared (PIR) sensor, magnetic field sensor, radio frequency (RF) sensor, light sensor, humidity sensor, pressure sensor, microphone, compass, or any other environmental sensor that obtains or provides a corresponding type of information about the environment in which the premises management device 1700 is located.

The processor 1708 can be a central processing unit (CPU) or other type of processor and can be communicably connected to the other components to receive and analyze data obtained by the sensor 1702, can transmit messages or packets that control operation of other components of the premises management device 1700 and/or external devices, and can process communications between the premises management device 1700 and other devices. The processor 1708 can execute instructions and/or computer executable components stored on the memory 1710. Such computer executable components can include, for example, a primary function component to control a primary function of the premises management device 1700 related to managing a premises, a communication component to locate and communicate with other compatible premises management devices, a computational component to process system related tasks, or any combination thereof

The memory 1710 or another memory in the premises management device 1700 can also be communicably connected to receive and store environmental data obtained by the sensor 1702. A communication interface 1706 can function to transmit and receive data using a wireless protocol, such as a WiFi™, Thread®, or other wireless interface, Ethernet® or other local network interface, Bluetooth® or other radio interface, or the like and can facilitate transmission and receipt of data by the premises management device 1700 to and from other devices.

The user interface (UI) 1704 can provide information and/or receive input from a user of the system 1600. The UI 1704 can include, for example, a speaker to output an audible sound when an event is detected by the premises management device 1700. Alternatively or additionally, the UI 1704 can include a light to be activated when an event is detected by the premises management device 1700. The UI 1704 can be relatively minimal, such as a liquid crystal display (LCD), light-emitting diode (LED) display, or limited-output display, or it can be a full-featured interface such as a touchscreen, keypad, or selection wheel with a click-button mechanism to enter input.

Internal components of the premises management device 1700 can transmit and receive data to and from one another via an internal bus 1712 or other mechanism. One or more components can be implemented in a single physical arrangement, such as where multiple components are implemented on a single integrated circuit. Premises management devices 1700 can include other components, and/or may not include all of the components illustrated.

The sensor 1702 can obtain data about the premises, and at least some of the data can be used to implement the security system. Through the bus 1712 and/or communication interface 1106, sensor data can be transmitted to or accessible by other components of the system 1600. Generally, two or more sensors 1702 on one or more premises management devices 1700 can generate data that can be coordinated by the primary system processor to determine a system response and/or infer a state of the environment. In one example, the primary system processor of the system 1600 can infer a state of intrusion based on data from entry detection sensors and motion sensors and, based on the determined state, further determine whether an unauthorized party is present and a location, within the premises, of the unauthorized party.

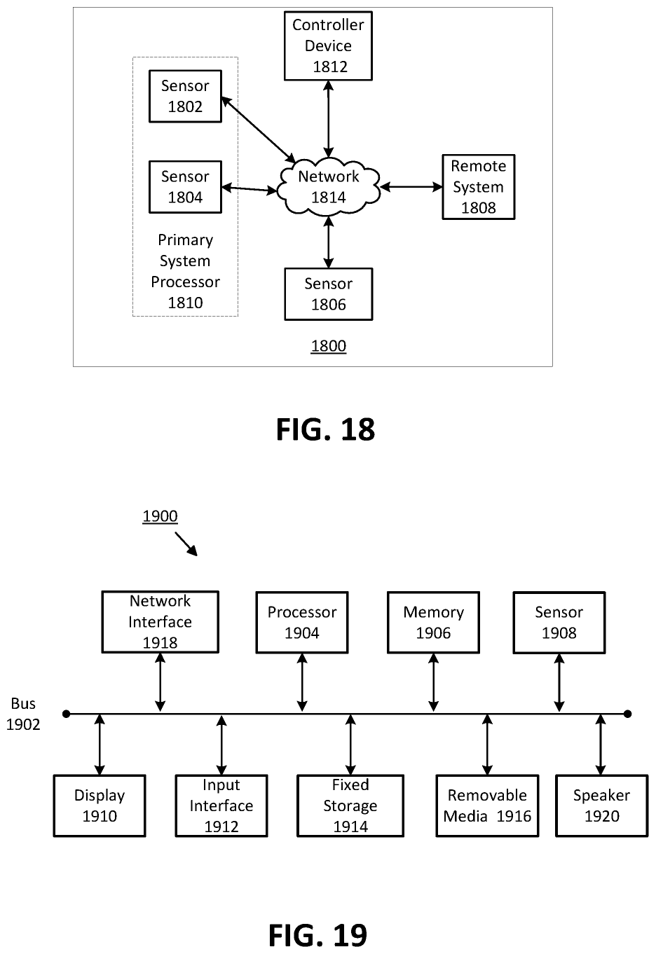

FIG. 18 is a block diagram of an example of an embodiment of a premises management system 1800. The premises management system 1800 can include security system features. System 1800 can be implemented over any suitable wired and/or wireless communication networks. One or more premises management devices, i.e., sensors 1802, 1804, 1806, and one or more controller devices 1812 can communicate via a local network 1814, such as a WiFi™ or other suitable network, with each other. The network 1814 can include a mesh-type network such as Thread®, which can provide network architecture and/or protocols for devices to communicate with one another. An authorized party can therefore interact with the premises management system 1800, for example, using the controller device 1812, which can communicate with the rest of the system 1800 via the network 1814.

The controller device 1812 and/or one or more of the sensors 1802, 1804, 1806, can be configured to implement a primary system processor 1810. The primary system processor 1810 can, for example, receive, aggregate, and/or analyze environmental information received from the sensors 1802, 1804, 1806, and the controller device 1812. Furthermore, a portion or percentage of the primary system processor 1810 can be implemented in a remote system 1808, such as a cloud-based reporting and/or analysis system. The remote system 1808 can, for example, independently aggregate data from multiple locations, provide instruction, software updates, and/or aggregated data to a controller 1812, primary system processor 1810, and/or sensors 1802, 1804, 1806.

The sensors 1802, 1804, 1806, can be disposed locally to one another, such as within a single dwelling, office space, building, room, or the like, or they may be disposed remote from each other, such as at various locations around a wide perimeter of a premises. In some embodiments, sensors 1802, 1804, 1806, can communicate directly with one or more remote systems 1808. The remote system 1808 can, for example, aggregate data from multiple locations, provide instruction, software updates, and/or aggregated data to the primary system processor 1810, controller device 1812, and/or sensors 1802, 1804, 1806. Additionally, remote system 1808 can refer to a system or subsystem that is a part of a third party monitoring service or a law enforcement service.

The premises management system illustrated in FIG. 18 can be a part of a smart-home environment, which can include a structure, such as a house, office building, garage, mobile home, or the like. The devices of the smart home environment, such as the sensors 1802, 1804, 1806, and the network 1814 can be integrated into a smart-home environment that does not include an entire structure, such as a single unit in an apartment building, condominium building, or office building.

The smart home environment can control and/or be coupled to devices outside of the structure. For example, one or more of the sensors 1802, 1804 can be located outside the structure at one or more distances from the structure (e.g., sensors 1802, 1804 can be disposed outside the structure, at points along a land perimeter on which the structure is located, or the like. One or more of the devices in the smart home environment may not be physically within the structure. For example, the controller 1812, which can receive input from the sensors 1802, 1804, can be located outside of the structure.

The structure of the smart-home environment can include a plurality of rooms, separated at least partly from each other via walls. The walls can include interior walls or exterior walls. Each room can further include a floor and a ceiling. Devices of the smart-home environment, such as the sensors 1802, 1804, can be mounted on, integrated with, and/or supported by a wall, floor, or ceiling of the structure.

The controller device 1812 can be a general or special-purpose controller. For example, one type of controller device 1812 can be a general-purpose computing device running one or more applications that collect and analyze data from one or more sensors 1802, 1804, 1806 within the home. In this case, the controller device 1812 can be implemented using, for example, a mobile computing device such as a mobile phone, a tablet computer, a laptop computer, a personal data assistant, or wearable technology. Another example of a controller device 1812 can be a special-purpose controller that is dedicated to a subset of functions, such as a security controller that collects, analyzes and provides access to sensor data primarily or exclusively as it relates to various security considerations for a premises. The controller device 1812 can be located locally with respect to the sensors 1802, 1804, 1806 with which it can communicate and from which it can obtain sensor data, such as in the case where it is positioned within a home that includes a home automation and/or sensor network. Alternatively or additionally, controller device 1812 can be remote from the sensors 1802, 1804, 1806, such as where the controller device 1812 is implemented as a cloud-based system that can communicate with multiple sensors 1802, 1804, 1806, which can be located at multiple locations and can be local or remote with respect to one another.

Sensors 1802, 1804, 1806 can communicate with each other, the controller device 1812, and the primary system processor 1810 within a private, secure, local communication network that can be implemented wired or wirelessly, and/or a sensor-specific network through which sensors 1802, 1804, 1806 can communicate with one another and/or with dedicated other devices. Alternatively, as illustrated in FIG. 18, one or more sensors 1802, 1804, 1806 can communicate via a common local network 1814, such as a Wi-Fi™, Thread®, or other suitable network, with each other, and/or with the controller 1812 and primary system processor 1810. Alternatively or additionally, sensors 1802, 1804, 1806 can communicate directly with a remote system 1808.

The smart-home environment, including the sensor network shown in FIG. 18, can include a plurality of premises management devices, including intelligent, multi-sensing, network-connected devices that can integrate seamlessly with each other and/or with a central server or a cloud-computing system (e.g., controller 1812 and/or remote system 1808) to provide home-security and smart-home features. Such devices can include one or more intelligent, multi-sensing, network-connected thermostats (e.g., “smart thermostats”), one or more intelligent, network-connected, multi-sensing hazard detection units (e.g., “smart hazard detectors”), one or more intelligent, multi-sensing, network-connected entryway interface devices (e.g., “smart doorbells”), or any combination thereof. The smart hazard detectors, smart thermostats, and smart doorbells can be, for example, the sensors 1802, 1804, 1806 illustrated in FIG. 18. These premises management devices can be used by the security system, but can also have separate, primary functions.

For example, a smart thermostat can detect ambient climate characteristics (e.g., temperature and/or humidity) and can accordingly control a heating, ventilating, and air conditioning (HVAC) system of the structure. For example, the ambient climate characteristics can be detected by sensors 1802, 1804, 1806 illustrated in FIG. 18, and the controller 1812 can control the HVAC system (not illustrated) of the structure. However, unusual changes in temperature of a given room can also provide data that can supplement a determination of whether a situation is a security concern, for example, detecting a rapid drop in temperature in a given room due to a broken in window.

As another example, a smart hazard detector can detect the presence of a hazardous substance or a substance indicative of a hazardous substance (e.g., smoke, fire, or carbon monoxide). For example, smoke, fire, and/or carbon monoxide can be detected by sensors 1802, 1804, 1806 illustrated in FIG. 18, and the controller 1812 can control an alarm system to provide a visual and/or audible alarm to the user of the smart-home environment. However, the speaker of the hazard detector can also be used to announce security related messages.

As another example, a smart doorbell can control doorbell functionality, detect a person's approach to or departure from a location (e.g., an outer door to the structure), and announce a person's approach or departure from the structure via an audible and/or visual message that can be output by a speaker and/or a display coupled to, for example, the controller 1812. However, the detection of an approach of an unknown party can provide data to the security system to supplement determining whether the presence of the unknown party is a security concern.

A smart-home environment can include one or more intelligent, multi-sensing, network-connected entry detectors (e.g., “smart entry detectors”) that can be specifically designed to function as part of a security subsystem. Such detectors can be or can include one or more of the sensors 1802, 1804, 1806 illustrated in FIG. 18. The smart entry detectors can be disposed at one or more windows, doors, and other entry points of the smart-home environment to detect when a window, door, or other entry point is opened, broken, breached, and/or compromised. The smart entry detectors can generate a corresponding signal to be provided to the controller 1812, primary system processor 1810, and/or the remote system 1808 when a window or door is opened, closed, breached, and/or compromised. In some embodiments of the security system, the alarm, which can be included with controller 1812 and/or coupled to the network 1814, may not arm unless all smart entry detectors (e.g., sensors 1802, 1804, 1806) indicate that all doors, windows, entryways, and the like are closed and/or that all smart entry detectors are armed.

The smart thermostats, the smart hazard detectors, the smart doorbells, the smart entry detectors, and other premise management devices of a smart-home environment (e.g., as illustrated as sensors 1802, 1804, 1806 of FIG. 18) can be communicatively connected to each other via the network 1814, and to the controller 1812, primary system processor 1810, and/or remote system 1808.

One or more users can control one or more of the network-connected smart devices in the smart-home environment using a network-connected computer or portable electronic device. In some examples, some or all of the users (e.g., individuals who live in the home) can register their mobile device, token and/or key fobs with the smart-home environment (e.g., with the controller 1812). Such registration can be made at a central server (e.g., the controller 1812 and/or the remote system 1808) to authenticate the user and/or the electronic device as being associated with the smart-home environment, and to provide permission to the user to use the electronic device to control the network-connected smart devices and the security system of the smart-home environment. A user can use their registered electronic device to remotely control the network-connected smart devices and security system of the smart-home environment, such as when the occupant is at work or on vacation. The user can also use their registered electronic device to control the network-connected smart devices when the user is located inside the smart-home environment.

As an alternative to or in addition to registering electronic devices, the smart-home environment can make inferences about which individuals live in the home and are therefore users and which electronic devices are associated with those individuals. As such, the smart-home environment can “learn” who is a user (e.g., an authorized user) and permit the electronic devices associated with those individuals to control the network-connected smart devices of the smart-home environment (e.g., devices communicatively coupled to the network 1814) including, in some embodiments, sensors used by or within the smart-home environment. Various types of notices and other information can be provided to users via messages sent to one or more user electronic devices. For example, the messages can be sent via e-mail, short message service (SMS), multimedia messaging service (MMS), unstructured supplementary service data (US SD), as well as any other type of messaging services and/or communication protocols.

FIG. 19 is a block diagram of an example of a computing device 1900 suitable for implementing certain devices. The computing device 1900 can be used to implement, for example, the controller device 1812 or a premises management device including sensors as described above. The computing device 1900 can be constructed as a custom-designed device or can be, for example, a special-purpose desktop computer, laptop computer, or mobile computing device such as a smart phone, tablet, personal data assistant, wearable technology, or the like.

The computing device 1900 can include a bus 1902 that interconnects major components of the computing device 1900. Such components can include a central processor 1904; a memory 1906 (such as Random Access Memory (RAM), Read-Only Memory (ROM), flash RAM, or the like), a sensor 1908 (which can include one or more sensors), a display 1910 (such as a display screen), an input interface 1912 (which can include one or more input devices such as a keyboard, mouse, keypad, touch pad, turn-wheel, and the like), a fixed storage 1914 (such as a hard drive, flash storage, and the like), a removable media component 1916 (operable to control and receive a solid-state memory device, an optical disk, a flash drive, and the like), a network interface 1918 (operable to communicate with one or more remote devices via a suitable network connection), and a speaker 1920 (to output an audible communication). In some embodiments the input interface 1912 and the display 1910 can be combined, such as in the form of a touch screen.

The bus 1902 can allow data communication between the central processor 1904 and one or more memory components 1914, 1916, which can include RAM, ROM, or other memory. Applications resident with the computing device 1900 generally can be stored on and accessed via a computer readable storage medium.

The fixed storage 1914 can be integral with the computing device 1900 or can be separate and accessed through other interfaces. The network interface 1918 can provide a direct connection to the premises management system and/or a remote server via a wired or wireless connection. The network interface 1918 can provide such connection using any suitable technique and protocol, including digital cellular telephone, WiFi™, Thread®, Bluetooth®, near field communications (NFC), and the like. For example, the network interface 1918 can allow the computing device 1900 to communicate with other components of the premises management system or other computers via one or more local, wide-area, or other communication networks.

The foregoing description, for purpose of explanation, has been described with reference to specific embodiments. However, the illustrative discussions above are not intended to be exhaustive or to limit embodiments of the disclosed subject matter to the precise forms disclosed. Many modifications and variations are possible in view of the above teachings. The embodiments were chosen and described in order to explain the principles of embodiments of the disclosed subject matter and their practical applications, to thereby enable others skilled in the art to utilize those embodiments as well as various embodiments with various modifications as may be suited to the particular use contemplated.

1. An adapter, comprising
a voltage doubler rectifier having a first switch and being configured to:
rectify a received voltage in response to the first switch being in a first position; and
rectify and effectively double the received voltage in response to the first switch being in a second position;
a first stage converter coupled to the voltage doubler rectifier and being a first type of converter, the first type of converter being one of an isolated converter or a non-isolated converter; and
a second stage converter coupled to the first stage converter and being a second type of converter, the second type of converter being one of the isolated converter or the non-isolated converter, the second type of converter being different from the first type of converter.

2. The adapter of claim 1, wherein the isolated converter comprises an LLC converter, an LCC converter, a flyback converter, a half-bridge converter, a full-bridge converter, a silicon controlled rectifier converter, a resonant converter, or a parallel resonant converter.

3. The adapter of claim 1, wherein the non-isolated converter comprises a buck-boost converter, a buck converter, or a boost converter.

4. The adapter of claim 1, wherein the voltage doubler rectifier comprises:
a first diode having:
a cathode of the first diode connected to a first node; and
an anode of the first diode connected to a second node;
a second diode having:
a cathode of the second diode connected to the first node; and
an anode of the second diode connected to a third node;
a third diode having:
a cathode of the third diode connected to the second node; and
an anode of the third diode connected to a fourth node;
a fourth diode having:
a cathode of the fourth diode connected to the third node; and
an anode of the fourth diode connected to the fourth node;
a first capacitor coupled between the first node and a fifth node;
a second capacitor coupled between the fourth node and the fifth node; and
the first switch coupled between the third node and the fifth node.

5. The adapter of claim 4, wherein the first switch comprises:
a first n-channel enhancement type metal-oxide-semiconductor field-effect transistor;
a fifth diode having:
a cathode of the fifth diode connected to a drain of the first n-channel enhancement type metal-oxide-semiconductor field-effect transistor; and
an anode of the fifth diode connected to a source of the first n-channel enhancement type metal-oxide-semiconductor field-effect transistor;
a second n-channel enhancement type metal-oxide-semiconductor field-effect transistor; and
a sixth diode having:
a cathode of the sixth diode connected to a drain of the second n-channel enhancement type metal-oxide-semiconductor field-effect transistor; and
an anode of the sixth diode connected to a source of the second n-channel enhancement type metal-oxide-semiconductor field-effect transistor,
wherein:
the source of the first n-channel enhancement type metal-oxide-semiconductor field-effect transistor is connected to a sixth node; and
the source of the second n-channel enhancement type metal-oxide-semiconductor field-effect transistor is connected to the sixth node.

6. The adapter of claim 1, further comprising a filter coupled to the voltage doubler rectifier.

7. The adapter of claim 6, wherein the filter is coupled between the voltage doubler rectifier and the first stage converter.

8. The adapter of claim 6, wherein the filter comprises:
a first inductor coupled between a first node and a second node;
a second inductor coupled between a third node and a fourth node;
a first capacitor coupled between the first node and the third node;
a second capacitor coupled between the second node and a ground; and
a third capacitor coupled between the fourth node and the ground.

9. The adapter of claim 1, further comprising a comparator configured to:
compare a voltage of an electrical power supply to a threshold voltage; and
produce, in response to a result of a comparison of the voltage of the electrical power supply to the threshold voltage, a signal to control a position of the first switch.

10. The adapter of claim 1, further comprising a bulk capacitor coupled between a first node and a second node, the first node being between the voltage doubler rectifier and the first stage converter, the second node being between the voltage doubler rectifier and the first stage converter.

11. The adapter of claim 1, further comprising a regulator configured to control an operation of the first stage converter to maintain a voltage at an output of the first stage converter within a range of voltages.

12. The adapter of claim 11, wherein the regulator is configured to control, in response to the voltage at the output being less than a threshold voltage, the operation of the first stage converter to maintain the voltage at the output of the first stage converter within the range of voltages.

13. The adapter of claim 1, wherein the first stage converter comprises:
a capacitor coupled between a first node and a second node;
a first inductor coupled between the second node and a third node;
a second inductor coupled between the third node and a fourth node;
a primary winding of a transformer, the primary winding coupled between the third node and the fourth node;
a first secondary winding of the transformer, the first secondary winding coupled between a fifth node and a sixth node;
a second secondary winding of the transformer, the second secondary winding coupled between the sixth node and a seventh node;
a second switch coupled between an eighth node and the first node;
a third switch coupled between the first node and the fourth node;
a fourth switch coupled between the fifth node and a ninth node; and
a fifth switch coupled between the seventh node and the ninth node.

14. The adapter of claim 13, wherein the first stage converter is configured to operate close to a resonant frequency.

15. The adapter of claim 13, wherein at least one of the second switch, the third switch, the fourth switch, and the fifth switch is configured to be controlled by at least one signal, the at least one signal having a duty cycle of fifty percent.

16. The adapter of claim 13, wherein the first stage converter is configured to be operated to achieve zero voltage switching for the first switch and the second switch.

17. The adapter of claim 13, wherein the first stage converter is configured to be operated to achieve zero current switching for the third switch and the fourth switch.

18. The adapter of claim 1, further comprising a regulator configured to control an operation of the second stage converter to maintain a voltage at an output of the second stage converter within a range of voltages.

19. The adapter of claim 18, wherein the regulator is configured to control, in response to the voltage at the output being less than a threshold voltage, the operation of the second stage converter to maintain the voltage at the output of the second stage converter within the range of voltages.

20. The adapter of claim 1, wherein the second stage converter comprises:
an inductor coupled between a first node and a second node;
a second switch coupled between the first node and a third node;
a third switch coupled between the second node and a fourth node;
a fourth switch coupled between the first node and a fifth node; and
a fifth switch coupled between the second node and the fifth node.

21. The adapter of claim 20, wherein at least one of the second switch, the third switch, the fourth switch, and the fifth switch is configured to be controlled by at least one signal, the at least one signal having at least one adjustable duty cycle.

22. The adapter of claim 21, further comprising voltage determination circuitry configured to:
determine, in response to a load being connected to the adapter, a voltage rating of a battery of the load; and
determine, in response to a result of a determination of the voltage rating, at least one specific duty cycle to cause a voltage at the fourth node to match the voltage rating; and
produce, in response to a determination of the at least one specific duty cycle, the at least one signal, the at least one signal having the at least one specific duty cycle.

23. The adapter of claim 22, wherein the voltage determination circuitry is configured to determine the voltage rating by receiving a signal from a Universal Serial Bus™ connector used to connect the load to the adapter.

24. A circuit, comprising:
a first diode having:
a cathode of the first diode connected to a first node; and
an anode of the first diode connected to a second node;
a second diode having:
a cathode of the second diode connected to the first node; and
an anode of the second diode connected to a third node;
a third diode having:
a cathode of the third diode connected to the second node; and
an anode of the third diode connected to a fourth node;
a fourth diode having:
a cathode of the fourth diode connected to the third node; and
an anode of the fourth diode connected to the fourth node;
a first capacitor coupled between the first node and a fifth node;
a second capacitor coupled between the fourth node and the fifth node;
a first switch coupled between the third node and the fifth node;
a second switch coupled between the first node and a sixth node;
a third switch coupled between the fourth node and the sixth node;
a third capacitor coupled between the sixth node and a seventh node;
a first inductor coupled between the seventh node and an eighth node;
a second inductor coupled between the eighth node and the fourth node;
a primary winding of a transformer, the primary winding coupled between the eighth node and the fourth node;
a first secondary winding of the transformer, the first secondary winding coupled between a ninth node and a tenth node;
a second secondary winding of the transformer, the second secondary winding coupled between the tenth node and an eleventh node;
a fourth switch coupled between the ninth node and a twelfth node;
a fifth switch coupled between the eleventh node and the twelfth node;
a sixth switch coupled between the tenth node and a thirteenth node;
a seventh switch coupled between the twelfth node and the thirteenth node;
a third inductor coupled between the thirteenth node and a fourteenth node;
an eighth switch coupled between the fourteenth node and a fifteenth node; and
a ninth switch coupled between the twelfth node and the fourteenth node.

25. A method for producing, from a voltage of an electrical power supply, a voltage that matches a voltage rating of a battery of an electronic device, the method comprising:
determining, by a circuit, the voltage rating of the battery of the electronic device, the electronic device separate from the circuit, but connected to the circuit;
determining, by the circuit, the voltage of the electrical power supply, the electrical power supply separate from the circuit, but connected to the circuit;
causing, by the circuit and in response to a determination that the voltage of the electrical power supply is greater than a threshold voltage, a switch to be in a first position;
causing, by the circuit and in response to a determination that the voltage of the electrical power supply is less than the threshold voltage, the switch to be in a second position;
rectifying, by the circuit, a voltage received by the electrical power supply to produce a rectified voltage;
effectively doubling, by the circuit and in response to the switch being in the second position, the rectified voltage;
converting, by a first stage of the circuit, the rectified voltage to produce an intermediate voltage; and
converting, by a second stage of the circuit, the intermediate voltage to produce the voltage that matches the voltage rating of the battery of the electronic device,
wherein:
the first stage being a first type, the first type being one of a type that includes galvanic isolation or a type that lacks galvanic isolation; and
the second stage being a second type, the second type being one of the type that includes galvanic isolation or the type that lacks galvanic isolation, the second type being different from the first type.
